(19) United States
(12) Patent Application Publication
(10) Pub. No.: US 2012/0327629 A1
(43) Pub. Date: Dec. 27, 2012

(54) TRANSCEIVER MODULE AND SHEET METAL HOUSING FOR TRANSCEIVER MODULE

(75) Inventors: George Kyi, Fremont, CA (US); Manfred Schmed, Livermore, CA (US)

(73) Assignee: FOURTE DESIGN & DEVELOPMENT, Fremont, CA (US)

(21) Appl. No.: 13/168,056

(22) Filed: Jun. 24, 2011

(51) Int. Cl. H05K 5/04; B65D 8/04; H05K 9/00

(52) U.S. Cl. 361/818; 220/660

(57) ABSTRACT

A transceiver module includes a sheet metal housing, an EMI finger, and a slot, wherein the EMI finger extends away from the sheet metal housing, and the slot is formed on the sheet metal housing and by the base of the EMI finger. By the slot, the sheet metal housing is prevented from getting stuck or jammed inside the cage upon removing the transceiver module from the cage.

### BACKGROUND OF THE INVENTION

1. Field of the Invention

This invention relates to a transceiver module and a sheet metal housing thereof, and more particularly, to the transceiver module having slots on the sheet metal housing for reducing the spring force when the transceiver module is inserted in a cage.

2. Description of the Prior Art

Computers and related peripheral equipment, as well as satellite and communication systems, have in the recent past evolved extremely rapidly. These systems require ever increasing data transfer rates to perform the highly complex task that drive the systems, such as digital signal processing, image analysis, and communications. With current demands, optical couplers are used to transfer signals over short and long distances between computers, between two circuit boards in one computer, and even between multiple chips on a single printed circuit board. The use of high speed optical signals in place of electrical interconnections increases the achievable data transfer rate.

An optical transmitter/receiver (transceiver) module typically includes both light emitting devices such as vertical cavity surface emitting lasers (VCSEL's) and light detecting device such as photodiodes. Driver/receiver circuitry modules, typically in the form of application specific integrated circuit (ASIC) chips, include driver circuitry for receiving signals from one device and drive the VCSEL's in response. The ASIC also includes receiver circuitry for receiving signals from the photodiodes and, in response, for processing those signals into an appropriate output. The combination of the VCSEL's, the photodiodes, and the ASIC circuitry is commonly referred to as an optical transceiver or a fiber optic transceiver.

Generally, the transceiver module includes a sheet metal housing, a PCB guide, EMI fingers, and a release mechanism. The PCB guide is attaches onto the sheet metal housing, the EMI fingers extend slightly away from the sheet metal housing, and the release mechanism is configured on the PCB guide. The sheet metal housing with the PCB guide and the EMI fingers can be received in a cage mounted on a PCB, and an interference fit between the EMI finger the cage is created when the transceiver module is inserted into the cage to provide an EMI shield. While the interference fit is created, each of the EMI fingers deflects and generates a spring force respectively.

The release mechanism is used for releasing the sheet metal housing from the cage, and then, the operator can remove the transceiver module from the cage. However, in the prior art, the above-mentioned spring force is often too strong to result in that the transceiver module tends to get stuck or jammed inside the cage, and damage may occur to the transceiver module or the cage once the operator exerts large force to remove the transceiver module from the cage.

Accordingly, it is an object of the present invention to provide a means to solve the problem that the transceiver module tends to get stuck or jammed inside the cage.

### SUMMARY OF THE INVENTION

One object of the present invention is to provide a novel sheet metal housing for the transceiver module to solve the problem in the prior art.

According to an embodiment of the invention, the sheet metal housing is used for a transceiver module which has an EMI finger extending away from the sheet metal housing, and the sheet metal housing includes a slot formed by the connecting part between the EMI finger and the sheet metal housing. By the slot, the spring force generated is weakened when the transceiver module is inserted inside the cage, and it prevent the sheet metal housing of the transceiver module from getting stuck or jammed inside the cage easily.

Another object of the present invention is to provide a novel transceiver module having slots on the base of EMI fingers to solve the problem in the prior art.

According to an embodiment of the invention, the transceiver module includes a sheet metal housing, an EMI finger, and a slot, wherein the EMI finger extends away from the sheet metal housing and the slot is formed on the sheet metal housing and by the base of the EMI finger. By the slot, the spring force generated is weakened when the transceiver module is inserted inside the cage, and it prevent the sheet metal housing from getting stuck or jammed inside the cage easily.

On the advantages and the spirit of the invention, it can be understood further by the following invention descriptions and attached drawings.

### BRIEF DESCRIPTION OF THE APPENDED DRAWINGS

FIG. 1 is a schematic drawing illustrating a transceiver module according to an embodiment of the invention.

FIG. 2 is a sectional drawing illustrating that the EMI fingers contact with the inside wall of the cage when the transceiver module is inserted inside the cage.

FIG. 3 is another view drawing illustrating the transceiver module in FIG. 1.

### DETAILED DESCRIPTION OF THE INVENTION

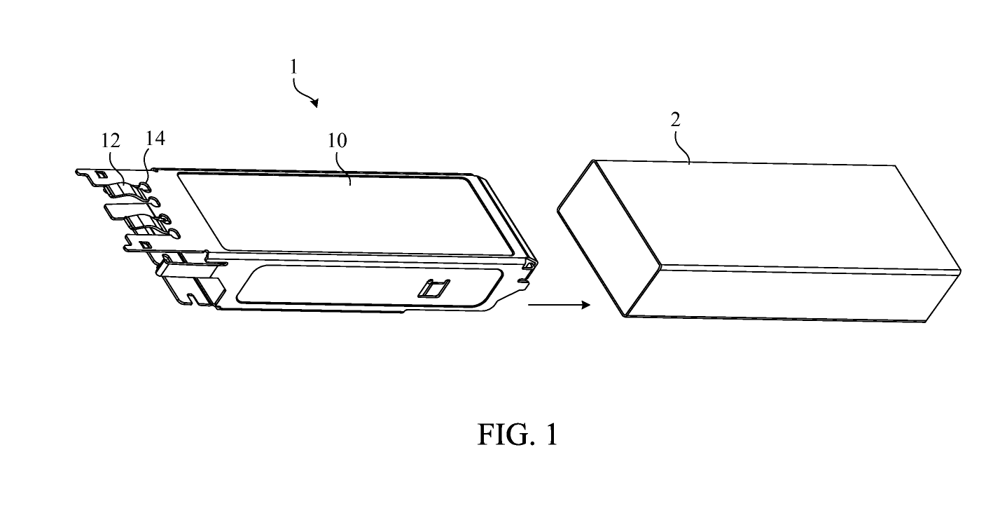

Please refer to FIG. 1. FIG. 1 is a schematic drawing illustrating a transceiver module 1 according to an embodiment of the invention. As shown in FIG. 1, the transceiver module 1 includes a sheet metal housing 10 and EMI fingers 12, wherein the EMI fingers 12 is configured on the sheet metal housing 10. The transceiver module 1 can be inserted into the cage 2 mounted on the PCB (not shown), so as to be the interface device for transforming the electrical signal and the optical signal.

In practice, the transceiver module further includes a PCB guide attaching one side of the sheet metal housing where the EMI fingers are located. The sheet metal housing and the PCB guide contain the interface elements therein, and the PCB guide is used for receiving the optical cable. Additionally, a release mechanism (not shown here) is configured on the PCB for releasing the total transceiver module from the cage.

In the embodiment, the EMI fingers 12 are formed by cutting one end of the sheet metal housing 10, and the EMI fingers 12 extend slightly away from the sheet metal housing 10, so that the EMI fingers 12 can contact with the cage 2 to create an electrical seal between the shield housing and the mating surface when the transceiver module 1 is inserted inside the cage 2.

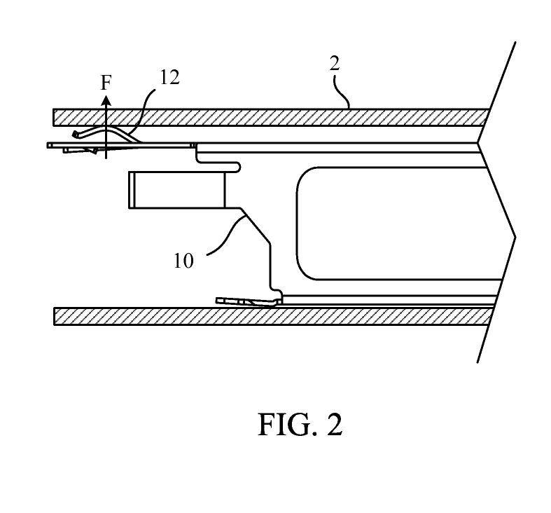

Please refer to FIG. 2, FIG. 2 is a sectional drawing illustrating that the EMI fingers 12 contact with the inside wall of the cage 2 when the transceiver module 1 is inserted inside the cage 2. As shown in FIG. 2, by extending away from the sheet metal housing 10 and a curved structure, the EMI fingers 12 contact with the inside wall of the cage 2 and deflect to generate a spring force F on the inside wall of the cage 2. The spring force F may cause the transceiver module 1 to get stuck or jammed inside the cage 2 by overpressing the inside wall of the cage 2.

The transceiver module 1 further includes four slots 14 located on the sheet metal housing 10 and by the bases of the EMI fingers 12 respectively, as shown in FIG. 1, wherein the bases of the EMI fingers 12 means the connecting parts between each of the EMI fingers 12 and the sheet metal housing 10. In practice, the slots could be cut by a wire EDM machine. By the slots 14, the spring force F generated by each of the EMI fingers 12 can be weakened, and then the sheet metal housing 10 would not tend to get stuck and jammed inside the cage 2 upon removing the transceiver module 1 from the cage 2. Therefore, the operator can exert less force to remove the transceiver module from the cage, and then the damage to the transceiver module or the cage is much easier to be avoided.

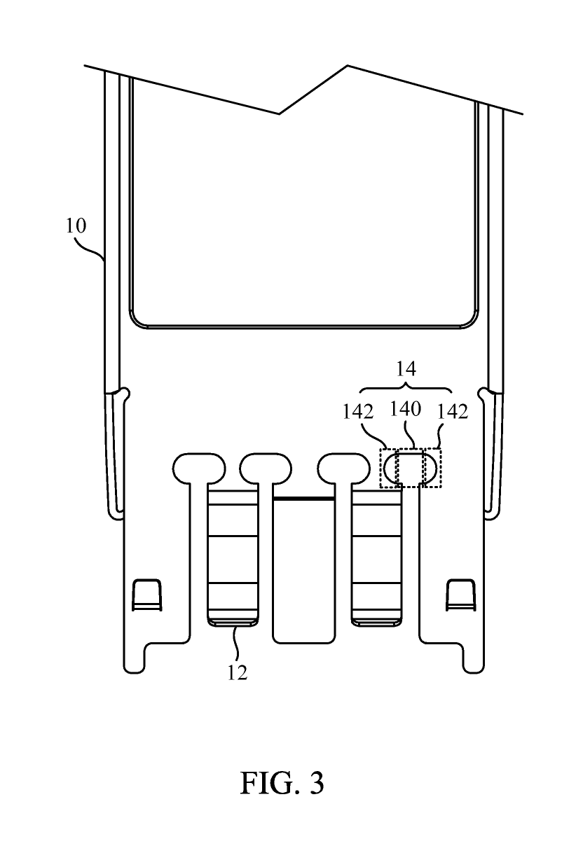

Please refer to FIG. 3. FIG. 3 is another view drawing illustrating the transceiver module 1 in FIG. 1. As shown in FIG. 3, each of the slots 14 further has a first part 140 and two second parts 142 located at two side of the first part 140 respectively. The first part 140 is in the form of an oblong, and the second parts 142 are in the form of two semicircles at the two end of the oblong respectively. In this embodiment, the length of the oblong is 1.5 mm and the radius of each semicircle is 0.5 mm, however, the sizes of the first part 140 and the second part 142 can be adjusted according to the size, the material, the quantity, or the shape of the EMI fingers. Furthermore, the forms of the slots also can be other forms, for example, the slots can be oval-shaped in other condition.

Compared to the prior art, the slots, formed on the sheet metal housing and by the base of the EMI fingers, in the present invention is capable of weakening the spring force when the transceiver module is inserted inside the cage. Accordingly, after releasing the transceiver module from the cage through the release mechanism, the sheet metal housing is prevented from getting stuck or jammed in the cage easily because the spring force which causes that the sheet metal housing tends to get stuck or jammed in the cage is weakened.

Although the present invention has been illustrated and described with reference to the preferred embodiment thereof, it should be understood that it is in no way limited to the details of such embodiment but is capable of numerous modifications within the scope of the appended claims.

What is claimed is:

1. A sheet metal housing for a transceiver module, the transceiver module having an EMI finger extending away from the sheet metal housing to form an interference fit with a cage, the sheet metal housing comprising:
a slot formed by the connecting part between the EMI finger and the sheet metal housing.

2. The sheet metal housing of claim 1, wherein the slot has a first part in the form of an oblong and a second part located at one side of the first part and in the form of a semicircle.

3. The sheet metal housing of claim 2, wherein the length of the oblong is 1. 5 mm and the radius of the semicircle is 0.5 mm.

4. The sheet metal housing of claim 1, wherein the slot is formed by a wire EDM machine.

5. A transceiver module, comprising:
a sheet metal housing;
an EMI finger extending away from the sheet metal housing to form an interference fit with a cage; and
a slot formed on the sheet metal housing and by the connecting part between the EMI finger and the sheet metal housing.

6. The transceiver module of claim 5, wherein the slot has a first part in the form of an oblong and a second part located at one side of the first part and in the form of a semicircle.

7. The transceiver module of claim 6, wherein the length of the oblong is 1.5 mm and the radius of the semicircle is 0.5 mm.

8. The transceiver module of claim 5, wherein the slot is formed by a wire EDM machine.
